(19) United States
(12) Patent Application Publication
(10) Pub. No.: US 2013/0048341 A1
(43) Pub. Date: Feb. 28, 2013

(54) MAGNETIC CABLE MANAGEMENT SYSTEM

(71) Applicants: Robert Walder, Plainville, VT (US); Thomas B. Stoddart, Nantucket, MA (US)

(72) Inventors: Robert Walder, Plainville, VT (US); Thomas B. Stoddart, Nantucket, MA (US)

(21) Appl. No.: 13/588,799

(22) Filed: Aug. 17, 2012

Related U.S. Application Data
(60) Provisional application No. 61/527,775, filed on Aug. 26, 2011.

(51) Int. Cl. H01B 7/40; H05K 13/04

(52) U.S. Cl. 174/135

(57) ABSTRACT

The present application is directed to methods and systems for cable management using a magnetic cable management module, which may comprise a magnet and a cable retaining channel. A cable may be placed into the cable retaining channel, which may compress or be expanded by the cable, with resulting pressure and friction securely retaining the cable. The cable management module may comprise a plurality of cable retaining channels of different gauges, allowing the module to be utilized with a wide variety of cables.

The module may be attached to a ferromagnetic surface or, in other embodiments, the module may be attached to a second module, such as magnetically through a piece of clothing. A fashion accessory may be magnetically attached to the module to enhance the user's appearance. A plurality of modules may be installed on a cable to securely and efficiently route the cable from endpoint to endpoint.

### RELATED APPLICATIONS

The present application claims priority to and the benefit of U.S. Provisional Patent Application No. 61/527,775, entitled “Magnetic Cable Management System,” filed Aug. 26, 2011, the entirety of which is hereby incorporated by reference.

### FIELD OF THE INVENTION

The methods and systems described herein relate generally to cable management. In particular, the methods and systems described herein relate to a magnetic cable management system.

### BACKGROUND OF THE INVENTION

Cable management, particularly of cables that are frequently moved or repositioned, can be tedious and difficult. While frequently utilized in professional, permanent or semi-permanent installations, cable management is often disregarded with personal electronics. For example, many smart phones, such as the iPhone line of smart phones manufactured by Apple, Inc. of Cupertino, Calif., come with a set of in-ear headphones (frequently referred to as “ear bud” style headphones). These headphones include a microphone and button, allowing a user wearing the headphones while listening to music or watching a video to pause, advance playback, answer or make telephone calls, or perform other functions. Furthermore, because of the headphones and microphone, the user does not need to hold the smart phone to their head during telephone calls, allowing the user to operate other functions of the smart phone simultaneously, such as taking notes, looking up directions, making reservations, sending email, etc.

These features are highly useful while the user is wearing the headphones. However, the user may also receive telephone calls while the headphones are in the user's pocket, where they are prone to tangling. Rather than attempting to untangle the headphones during the brief period while the phone rings prior to the call being redirected to voice mail, users tend to not use the headphones and integrated microphone during such calls. Unfortunately, this makes simultaneously operating other functions of the smart phone difficult, if not impossible

One solution abandons cable management completely, instead using earphones and microphones connected via short-range wireless communication protocols such as Bluetooth. However, Bluetooth microphones tend to be expensive, require frequent recharging, tend to be single-ear only and inadequate for music or video playback, and may not be particularly attractive. Other solutions include spring-loaded cord keepers that retract the headphones and plug when not in use. While useful at preventing tangles, these cord keepers tend to be large and ungainly, unpleasantly hanging on the cord while the user is wearing the headphones.

### SUMMARY OF THE INVENTION

The present application is directed to methods and systems for cable management using magnetic cable management modules. A cable management module may comprise a magnet and a cable retaining channel. A cable may be placed into the cable retaining channel, which may compress the cable or be expanded by the cable, with resulting pressure and friction securely retaining the cable. In some embodiments, the cable management module may comprise a plurality of cable retaining channels of different gauges, allowing the cable management module to be utilized with a wide variety of cables.

In some embodiments, the module may be attached to a ferromagnetic surface, while in other embodiments, the module may be attached to a second module. In a further embodiment, the module may be magnetically attached to a second module through a piece of clothing. In a still further embodiment, a fashion accessory may be magnetically attached to the module to enhance the user's appearance. In some embodiments, a plurality of modules may be installed on a cable to securely and efficiently route the cable from endpoint to endpoint.

In one aspect, the present application is directed to a cable management system. The cable management system includes a plurality of cable management modules, each comprising an enclosure comprising a first portion and an attached second portion, the first portion encapsulating a magnetic material, and the second portion comprising a compressible material forming a cable retaining channel, the cable retaining channel having an inside diameter of less than or equal to the diameter of a cable to be retained.

In one embodiment, the cable retaining channel of each cable management module extends across a face of the enclosure. In another embodiment, the cable retaining channel of each cable management module is open along the length of the channel to allow insertion of the cable. In still another embodiment, the cable retaining channel of each cable management module is encapsulated by the first portion of said cable management module. In yet still another embodiment, a first cable management module is configured to be magnetically attached to a second cable management module, and a third cable management module is configured to be magnetically attached to a magnetic transducer connected to a cable to be retained.

In some embodiments, the second portion of each cable management module further comprises a compressible material forming a plurality of cable retaining channels extending across a face of the enclosure, each cable retaining channel having a different diameter or cross-sectional profile. In other embodiments, the second portion of each cable management module further comprises a compressible material forming a second cable retaining channel extending across a second face of the enclosure, each cable retaining channel having a different diameter or cross-sectional profile. In still other embodiments, the first portion and the second portion of each cable management module are attached along a face of the second portion of said cable management module. In still yet other embodiments, one of the first portion and the second portion of each cable management module encapsulates the other of said first portion and second portion of said cable management module.

In one embodiment, the first portion of each cable management module further comprises a channel corresponding to dimensions of the second portion of said cable management module, and the second portion is attached within the channel of said first portion. In a further embodiment, the first portion of each cable management module further comprises a plurality of channels corresponding to dimensions of a corresponding plurality of second portions of said cable management module, each second portion attached within a corresponding channel of said first portion.

In some embodiments, a surface of a cable retaining channel of each cable management module comprises at least one ridge or scale. In other embodiments, each cable management module further comprises a third portion magnetically attached to one of the second portion or first portion of said cable management module. In a further embodiment, the third portion comprises a fashion accessory.

In some embodiments, the cable management system includes a cable connected to one or more audio transducers, a portion of the cable retained by each cable retaining channel of the plurality of cable management modules. In other embodiments, each cable management module further comprises a third portion forming an opposing surface of the cable retaining channel from a surface of the second portion. In a further embodiment, the third portion encapsulates a magnetic material. In another further embodiment, the second portion of each cable management module comprises a hook to form the cable retaining channel. In a still further embodiment, the third portion is attached to the first portion or second portion via at least one spring. In another still further embodiment, the third portion is magnetically repelled from the first portion, and wherein each cable management module further comprises at least one clip to constrain movement of the first and third portions.

The details of various embodiments of the invention are set forth in the accompanying drawings and the description below.

### BRIEF DESCRIPTION OF THE FIGURES

The foregoing and other objects, aspects, features, and advantages of the invention will become more apparent and better understood by referring to the following description taken in conjunction with the accompanying drawings, in which:

FIG. 1A is an illustration of an embodiment of in-ear headphones which may suffer from cable management issues;

FIGS. 1B-1D are illustrations of embodiments of utilizing in-ear headphones experiencing cable management issues;

FIG. 2A is an isometric view of an embodiment of a cable management module;

FIGS. 2B and 2C are top and bottom views, respectively, of the embodiment of the cable management module depicted in FIG. 2A;

FIG. 2D are illustrations of side views of different embodiments of a cable management module;

FIG. 2E is an illustration of an embodiment of a cable management system installed on in-ear headphones;

FIG. 2F is an illustration of use of in-ear headphones with an embodiment of a cable management system;

FIG. 2G is an illustration of a storage configuration for in-hear headphones with an embodiment of a cable management system;

FIG. 3A is an isometric view of another embodiment of a cable management module with multiple cable gauge capability;

FIG. 3B is a top view of the embodiment of the cable management module depicted in FIG. 3A;

FIG. 3C illustrates top views of additional embodiments of cable management modules;

FIG. 3D is an isometric view of yet another embodiment of a cable management module with multiple cable gauge capability;

FIG. 3E illustrates isometric views of additional embodiments of cable management modules;

FIG. 3F is an isometric view of still yet another embodiment of a cable management module;

FIG. 3G is an illustration of an another embodiment of a cable management system installed on in-ear headphones;

FIG. 3H is an illustration of an embodiment of a cable management module with removable insert;

FIG. 3I is an illustration of another embodiment of a cable management module with removable inserts;

FIGS. 4A-4C are front, top, and isometric views, respectively, of yet another embodiment of a cable management module;

FIG. 4D is an isometric view of still yet another embodiment of a cable management module;

FIG. 5A-5C are top, bottom, and front views, respectively, of yet still another embodiment of a cable management module;

FIGS. 5D and 5E are section views of an embodiment of the cable management module of FIGS. 5A-5C in an unpressed and pressed state, respectively;

FIGS. 6A-6C are top, section, and isometric views of yet another embodiment of a cable management module;

FIG. 7A is an isometric view of still yet another embodiment of a cable management module;

FIG. 7B is a section view of an embodiment of a channel of a cable management module;

FIGS. 8A and 8B are isometric views of embodiments of channels of a cable management module;

FIG. 9 is an isometric view of an embodiment of a fashion accessory for a cable management module; and

FIG. 10 is an illustration of use of an embodiment of a cable management module for cable management.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements.

### DETAILED DESCRIPTION OF THE INVENTION

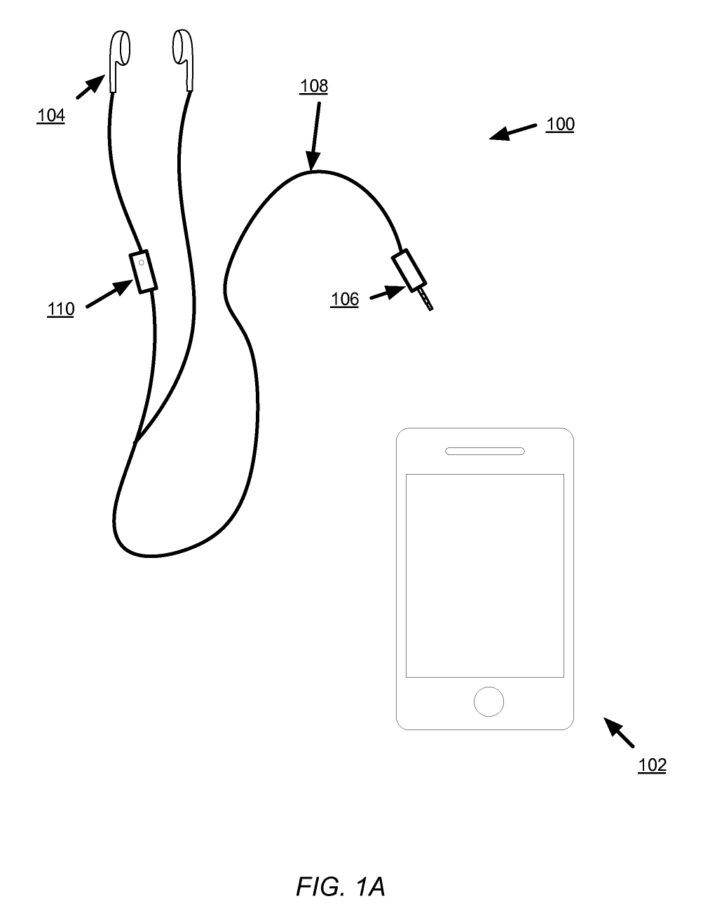

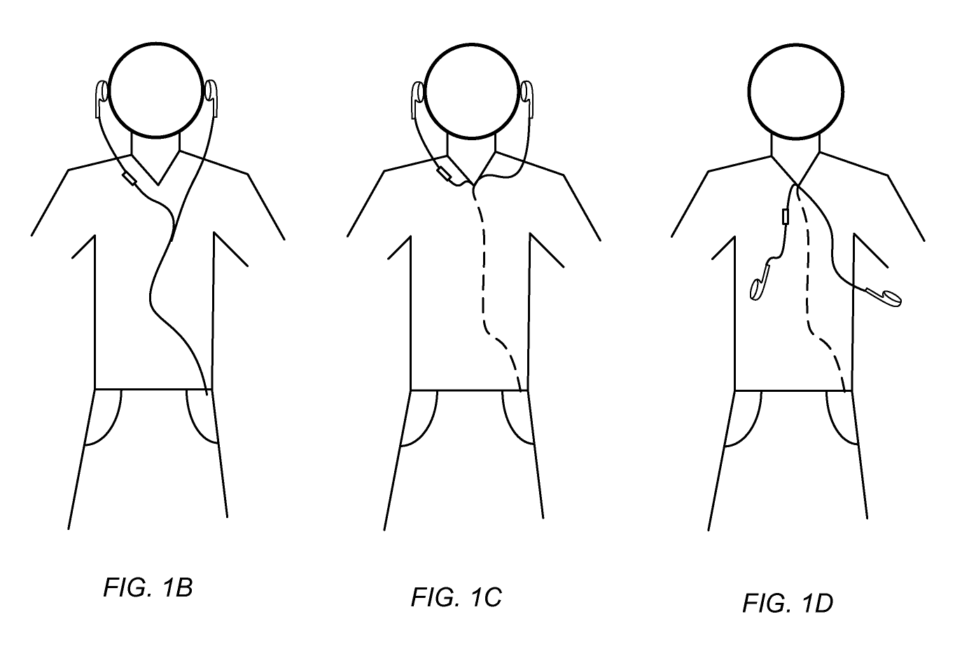

Prior to discussing methods and systems of cable management, it may be helpful to first describe problems and issues with cable management, particularly with small personal electronics. Referring first to FIG. 1A, illustrated is an embodiment of in-ear headphones 100 which may suffer from cable management issues. In-ear headphones 100 may be used with a smart phone or device 102, such as any models of Apple iPhone; any of the models of Droid smart phones manufactured by HTC Corporation of Taiwan, Republic of China; any of the models of BlackBerry smart phones manufactured by Research in Motion, Limited of Ontario, Canada; or any other smart phones. In some embodiments, in-ear headphones 100 may also be used with a media player, such as any of the line of iPod media players manufactured by Apple, Inc.; any of the models of Sansa media players manufactured by SanDisk Corporation of Milpitas, Calif.; or any other type and form of media player. In still other embodiments, in-ear headphones 100 may be used with any form of electronic device, including tablet computers, laptop computers, netbook computers, desktop computers, compact disc (CD) or digital versatile disc (DVD) players, portable gaming devices such as the Nintendo DS manufactured by Nintendo Corporation of Kyoto, Japan or the PlayStation Portable manufactured by Sony Corporation of Tokyo, Japan, or any other type and form of device. Although illustrated as in-ear or ear bud style headphones, in many embodiments, headphones 100 may be circumaural or supra-aural headsets, with each transducer joined by an over- or behind-the head band.

In many embodiments, a headphone 100 may comprise one (for mono use) or two (for stereo use) audio transducers 104, sometimes referred to as ear pieces, ear buds, or speakers. Transducers 104 may be of various types, but are most frequently moving coil drivers or dynamic drivers, and may include a permanent magnets of ceramic or ferrite composites, rare-earth magnets such as neodymium-iron-boron alloys (referred to generally as neodymium magnets), or any other type of magnet. Because of the magnet, transducers 104 may be attracted to other magnets, a feature which is exploited by the systems discussed herein and discussed in more detail below.

In some embodiments, transducers 104 may be connected via a cable 108 to a plug 106. In many embodiments, as illustrated, cable 108 may comprise two upper portions, each connected to a transducer 104, and a lower portion connected between the two upper portions and a plug 106, the overall cable 108 forming a Y-shape. In many embodiments, the lower portion of cable 108 may be a single cable with multiple conductors or wires, while in other embodiments, the lower portion of cable 108 may be two parallel cables, one for each transducer. This latter embodiment may be easier to manufacture, for example. In different embodiments of headphones 100, cable 108 may be different gauges or thicknesses. In many embodiments, cable 108 may include a compressible jacket of rubber or other similar material.

Plug 106 may comprise any type of plug for connection to a device 102. In many embodiments, plug 106 may comprise an ⅛th inch three-conductor or “tip-ring-sleeve” (TRS) plug. In some embodiments, such as embodiments of headphones 100 incorporating a microphone 110, plug 106 may comprise a four-conductor or TRRS plug.

In some embodiments, headphones 100 may include a microphone 110. Although illustrated on an upper portion of cable 108, in some embodiments, microphone 110 may be incorporated into or attached to one transducer 104, may be incorporated in an element joining both upper portions of cable 108 and the lower portion of cable 108, may be in-line with the lower portion of cable 108, or may be deployed in any other configuration. In some embodiments, microphone 110 may incorporate a switch or button for controlling one or more features of the device 102.

Because of the length of cable 108, headphones 100 may become easily tangled when stored, such as in a user's pocket during non-use. Even during use, cable 108 may swing annoyingly or otherwise interfere with the user's enjoyment. For example, as shown in FIG. 1B, in many embodiments, a user may have a device 102 (not illustrated) in a pocket, while wearing headphones 100. Cable 108 may then run from the user's ears to the user's pocket, swinging freely as the user moves. If the user is wearing the headphones while running, for example, cable 108 may bounce wildly and become tangled with the user's hand, potentially forcefully and painfully ripping one or both transducers from the user's ears.

In an attempt to mitigate this, many users run cable 108 under a shirt, as illustrated in FIG. 1C. While this prevents the cable from bouncing, if the user removes the transducers from his or her ears, such as to converse with another person, the transducers may swing annoyingly as illustrated in FIG. 1D. Furthermore, this solution may be unavailable if a user's shirt is tucked in, or if the user is wearing clothing that prevents them from running cable 108 beneath the clothing. Accordingly, many users remove headphones entirely when not in use, returning the headphones to a pocket, purse, or bag and potentially tangling them.

In an embodiment of a solution to these cable management issues, a plurality of cable management modules may be installed on cable 108. Each cable management module may incorporate a magnet and a cable retaining channel for securely holding cable 108. In storage, each cable management module may magnetically attach to one or more other cable management modules, preventing long runs of cable 108 that may be tangled. In use, cable management modules may be positioned on either side of items of clothing, securely holding cable 108 in place and out of the way of the user's arms.

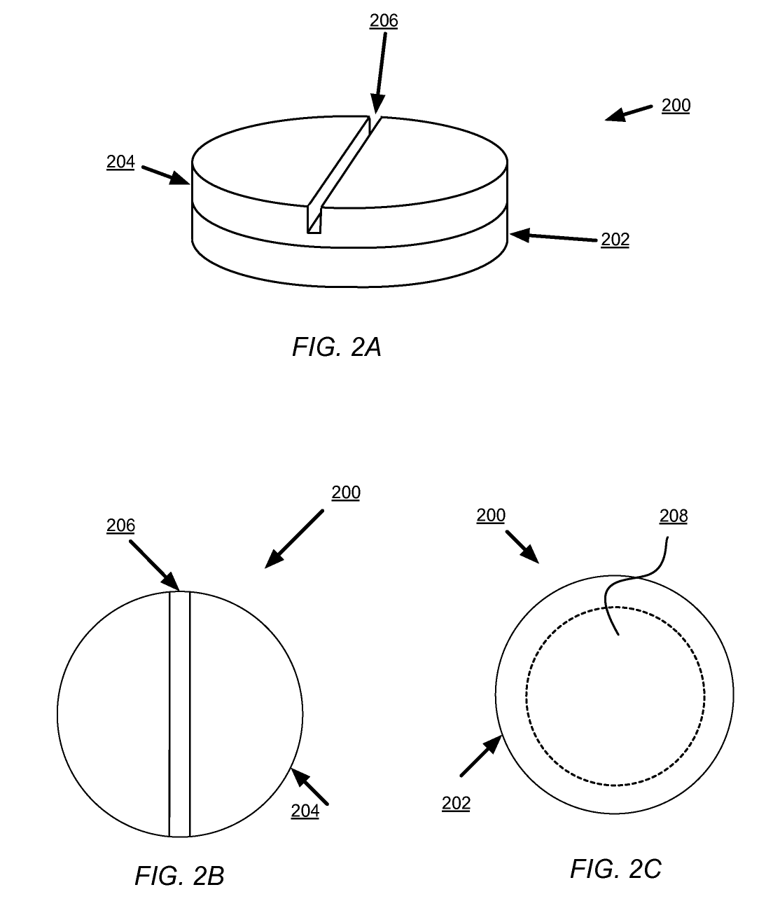

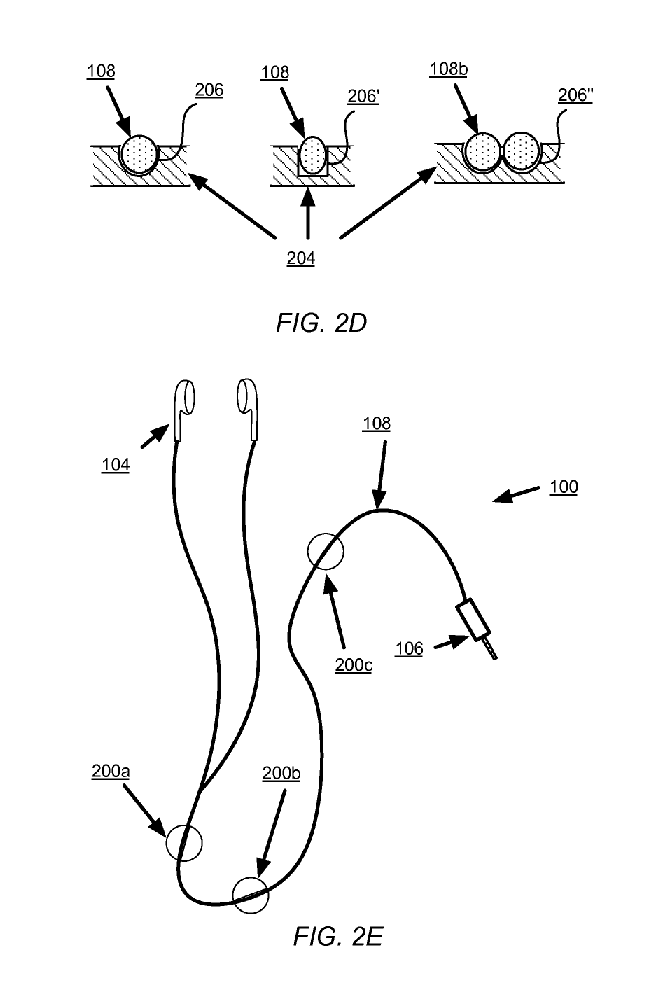

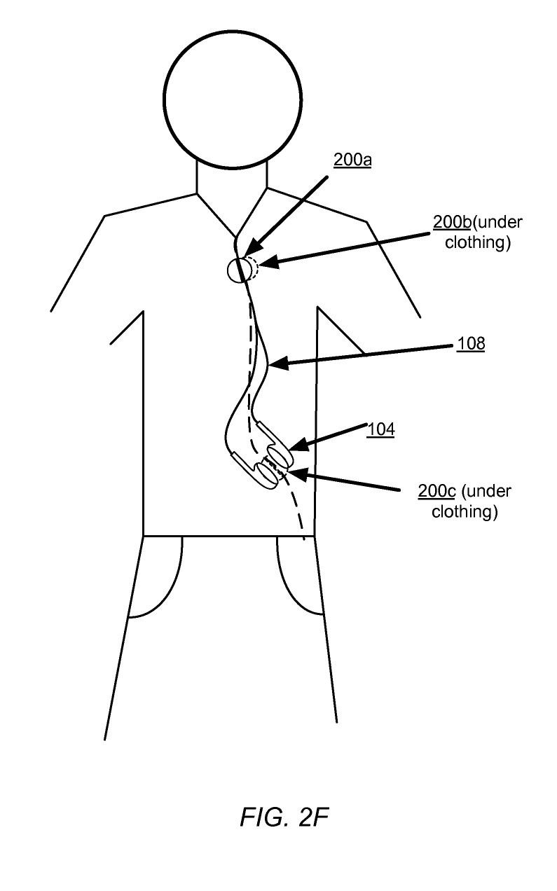

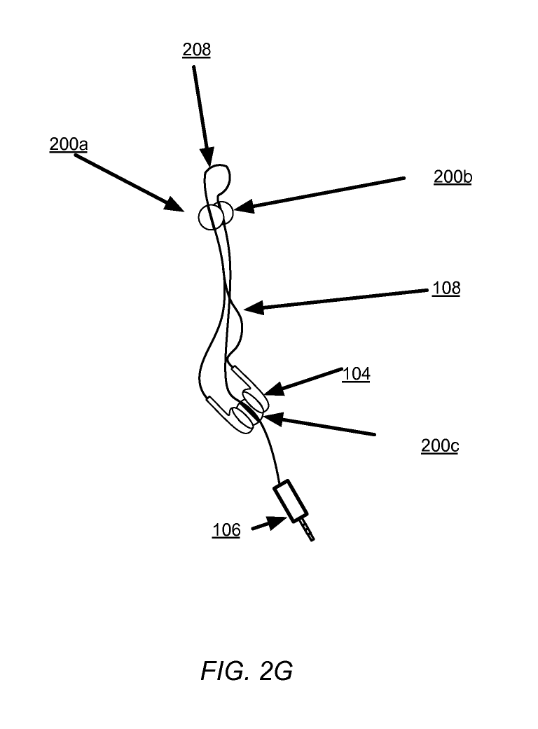

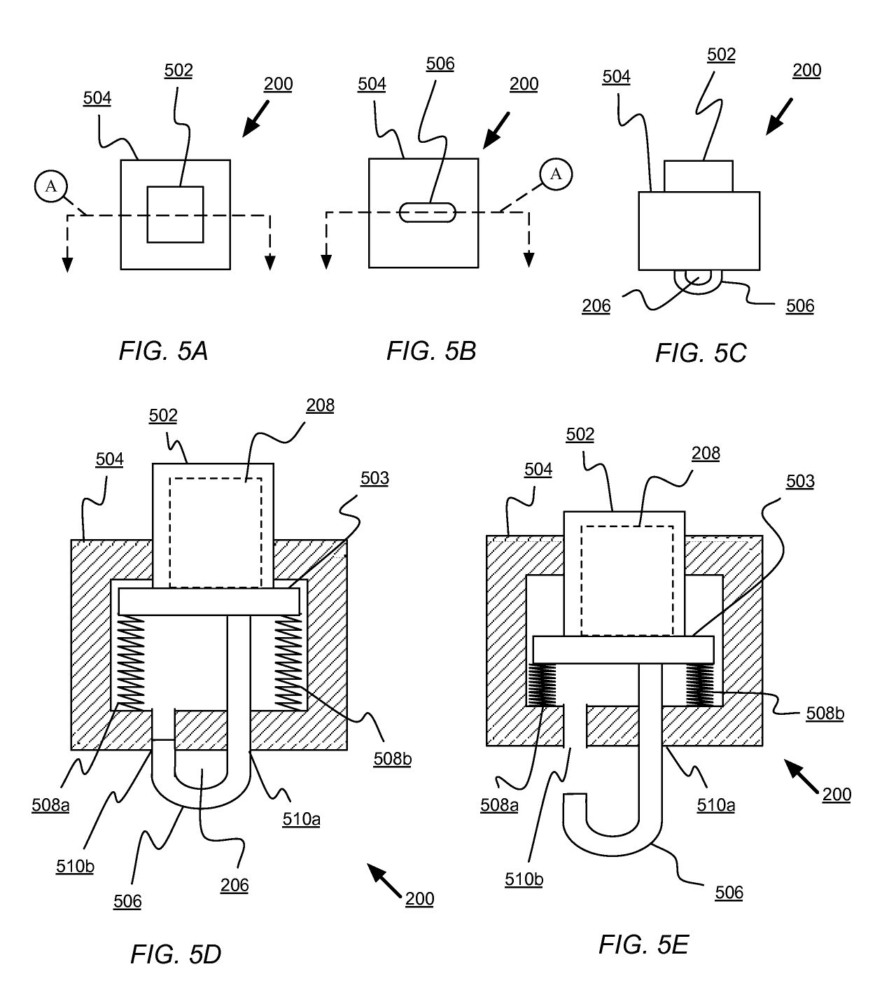

Referring to FIG. 2A, illustrated is an isometric view of an embodiment of a cable management module 200. In brief overview, cable management module 200 may comprise a lower portion 202, an upper portion 204, and one or more cable retaining channel(s) 206. Cable management modules 200 may be of any size, depending on purpose. For example, a cable management module for a headphone cable may be very small, such as a quarter inch or half inch in diameter or width or smaller, while a cable management module for data or electrical cables, discussed in more detail below in connection with FIG. 5, may be much larger, such as an inch or two in diameter or width or larger.

Still referring to FIG. 2A and in more detail, a cable management module 200 may comprise a lower portion 202 and upper portion 204, which may be made of the same or different materials. Lower portion 202 may be made of a magnetic material, or may encapsulate a magnetic material in a second material. For example, referring briefly to FIG. 2C, illustrated is a bottom view of the embodiment of the cable management module 200 of FIG. 2A incorporating an encapsulated magnet 208 in lower portion 202. Lower portion 202 may be a molded or pressed plastic or polymer, such as ABS plastic, fluroplastic, polycarbonate (PC) or polyethylene (PE) plastic; or may be metal, rubber or a similar material, or any other type of material. In some embodiments, for fashion purposes or to be kinesthetically pleasing to a user, lower portion 202 may be cloth, felt, silk, or any other type of material.

Still referring to FIG. 2C, magnet 208 may comprise any type or form of permanent magnet, including rare-earth magnets such as neodymium magnets, ferrite or ceramic magnets, or any other type of magnet. Although illustrated as a cylinder, in many embodiments, magnet 208 may comprise a cubic prism, a sphere, a rectangular prism, or any other shape. In many embodiments, magnet 208 may be oriented with poles axially through cable management module 200. For example, in one such embodiment, from the view of FIG. 2C, one pole may be oriented toward the viewer and one pole oriented away. In other embodiments, magnet 208 may be oriented in other directions.

Referring back to FIG. 2A, in some embodiments, upper portion 204 may comprise a surface of the cable management module 200 etched, notched, or otherwise configured with a cable retaining channel 206. Upper portion 204 may be of the same material as lower portion 202 or may be of a different material than lower portion 202. In some embodiments, upper portion 202 may comprise a compressible material, such as rubber, silicone, or a similar material, such that a cable may be pushed into a cable retaining channel 206 of smaller width than the cable, with the material squeezing the cable to provide secure grip and retention.

A cable management module 200 may include one or more cable retaining channel(s) 206, also shown in top view in FIG. 2B, for securely holding a cable during use and storage. Cable retaining channel 206 may be etched into, molded from, drilled through, or otherwise configured either across a surface of or through a cable management module 200. In some embodiments, discussed in more detail below, a cable management module 200 may be installed around a cable, or may be installed onto the cable during manufacture. In other embodiments, a cable management module 200 may be installed by a user, by the user pressing a cable into a cable retaining channel 206.

Referring now to FIG. 2D, illustrated are side views of different embodiments of cable retaining channels 206, 206′, and 206″ for a cable management module 200. As shown, in some embodiments, a cable retaining channel 206 may be circular or semi-circular in cross-section. The semi-circular cross-section may be 180 degrees of a circle in some embodiments, while in other embodiments, the semi-circular cross-section may be greater than 180 degrees, such that an opening to the channel is smaller than the maximum diameter of the channel. The latter may be useful in embodiments where upper portion 204 is a non-compressible material, such as ABS plastic, and a cable 108 includes a compressible outer jacket or insulation, as the cable may be pressed into the channel and securely retained by the channel. Similarly, such embodiments may be useful where cable 108 is non-compressible, and upper portion 204 is compressible.

In other embodiments, a cable retaining channel 206′ may comprise a square or rectangular cross section. In such embodiments, the width of channel 206′ may be less than the diameter of a cable 108, such that cable 108 is compressed when pressed into the channel, as shown. This may aid in securely retaining cable 108.

In still other embodiments, such as where cable 108 comprises parallel joined cables or conductors, cable retaining channel 206″ may be in a dual-channel configuration as shown. In such embodiments, each channel may have either a semi-circular cross section or a square or rectangular cross section, as discussed above.

Although illustrated with cable 108 protruding above the surface of upper portion 204 or channels 206, 206′, or 206″, in many embodiments, channels 206, 206′, or 206″ may be of sufficient depth such that cable 108 is fully retained within the channel.

Referring now to FIG. 2E, illustrated is an embodiment of a cable management system installed on in-ear headphones 100. The system may comprise a plurality of cable management modules 200a-200c which may be installed on cable 108, or cable 108 may be pressed into a cable retaining channel 206 of each cable management module 200a-200c as shown. In some embodiments, two cable management modules 200 may be employed, while in other embodiments, three, four, or any other number of cable management modules may be utilized. In still other embodiments, a single cable management module 200 may be installed, for aid in storing the cable.

FIG. 2F is an illustration of use of in-ear headphones with an embodiment of a cable management system illustrated in FIG. 2E. As shown, a user may run a cable 108 from a device 102 in a pocket under clothing, with cable management modules 200c, 200b left underneath the user's shirt. Cable management module 200a may be outside of the user's clothing and may magnetically attach to cable management module 200b through the user's clothing, securing cable 108 in place at the top of the user's shirt, and preventing cable 108 from bouncing while the user moves. As shown, when the user removes transducers 104 from the user's ears, the transducers may hang naturally in a position to attach magnetically to cable management module 200c through the user's clothing, due to the permanent magnet in each transducer 104. Accordingly, the headphones are entirely secured to the user's shirt at one end via cable management modules 200a and 200b, and at the other end via cable management module 200c and the transducers 104.

Although only three cable management modules are illustrated, additional modules may be employed to more securely route cable 108. For example, in an embodiment in which device 102 is held in an armband of the user, such as a media player for use when jogging or bicycling, cable management modules may be employed at the user's shirt sleeve in addition to collar, to securely route cable 108 through the user's shirt without pulling as the user moves.

In still other embodiments, such as where a user's shirt is tucked in, or the user is wearing a dress or other clothing that does not allow routing cable 108 from a pocket under the user's shirt, the user may place one or more cable management modules 200 under clothing without first installing them on a cable 108. For example, the user may place a first cable management module 200 under an item of clothing, and then allow a second cable management module 200 installed on a cable 108 to magnetically attach to the first cable management module, securing each module in place on the clothing and retaining the cable on the outside of the user's clothing. Similarly, in an embodiment in which cable 108 was outside the user's clothing but similarly routed as illustrated in FIG. 2F, the user could place cable management module 200b on the outside of the collar and cable management module 200a inside the collar to securely hold cable 108 in place.

Referring briefly to FIG. 2G, illustrated is an embodiment of a storage configuration for in-hear headphones with an embodiment of a cable management system. As discussed above, a first cable management module 200a installed on cable 108 may magnetically attach to a second cable management module 200b installed on cable 108, and transducers 104 may attach to a third cable management module 200c installed on cable 108. In such embodiments, a loop of wire 208 may be formed between cable management modules 200a and 200b. This loop 208 may be hung on a hook or other element, allowing gravity to keep cable 108 straight and tangle-free. Even where the headphones are placed in a user's pocket, purse, bag, or other container, tangling may be significantly reduced or eliminated due to the shortened inter-module cable lengths. In further embodiments, cable management modules 200a and 200b may further be magnetically attached to cable management module 200c, further reducing inter-module cable lengths and tangling possibilities.

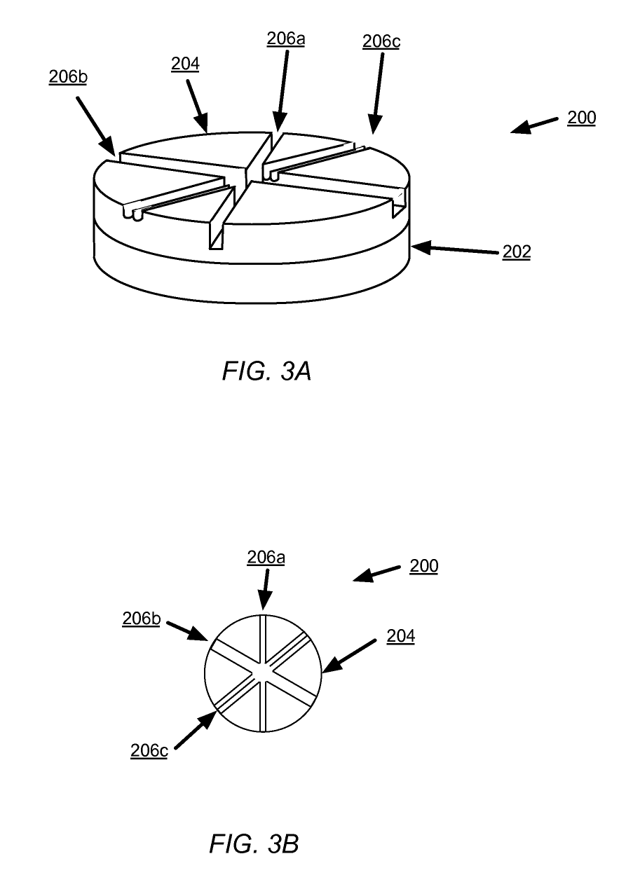

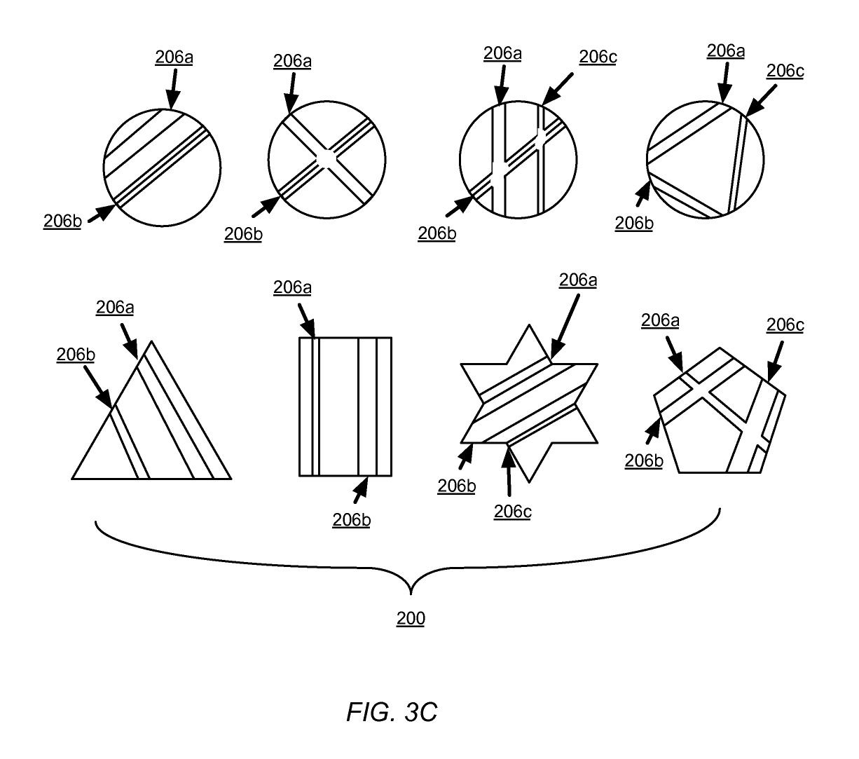

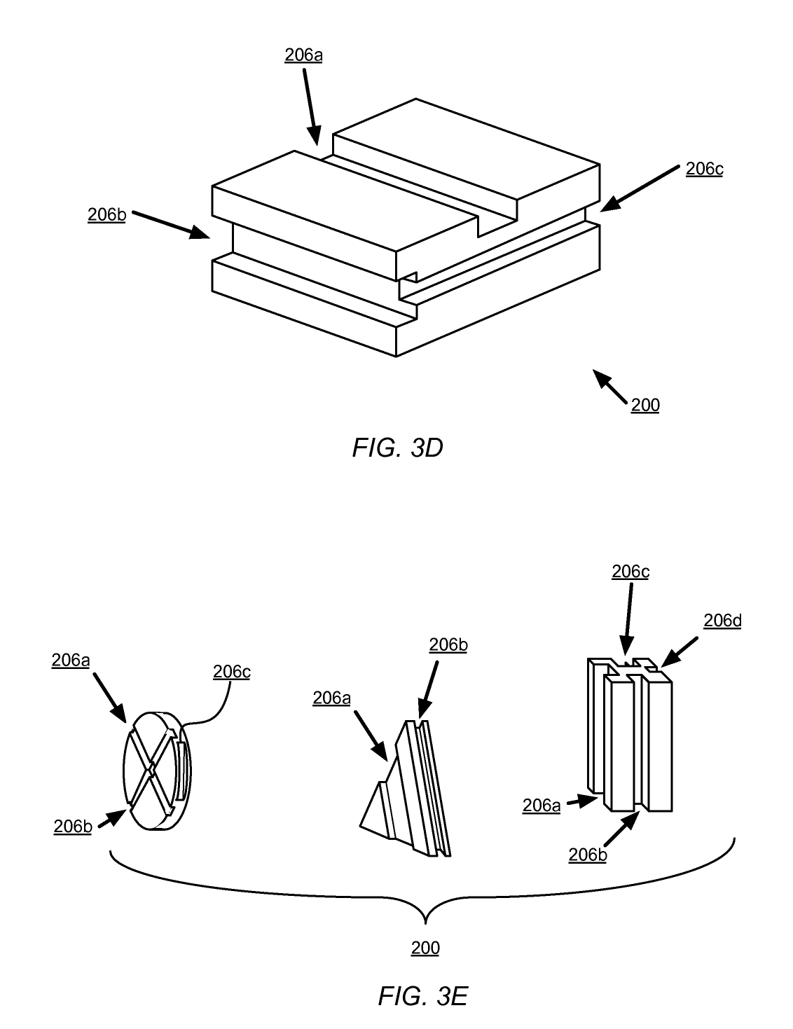

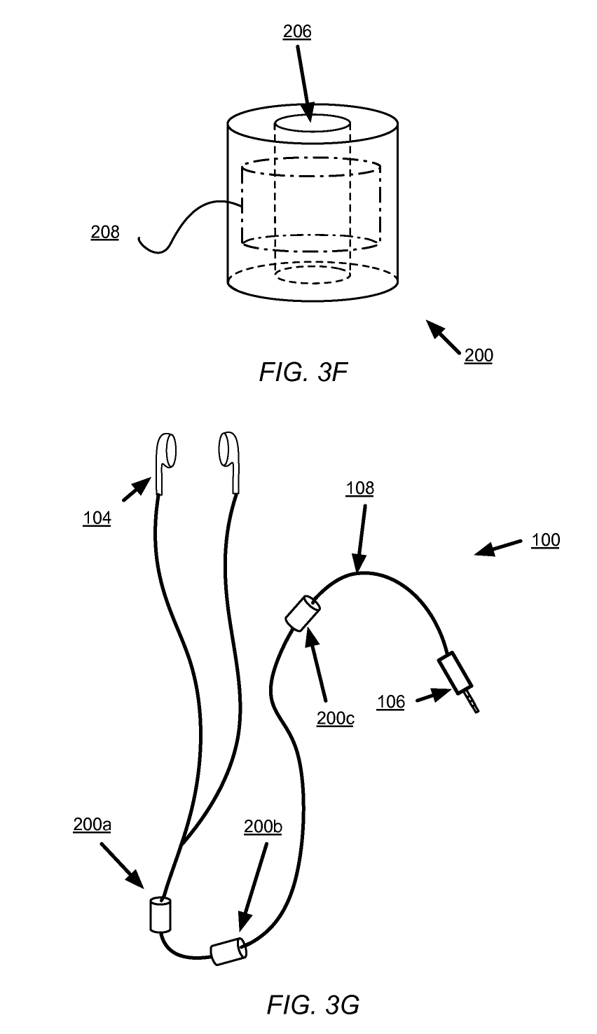

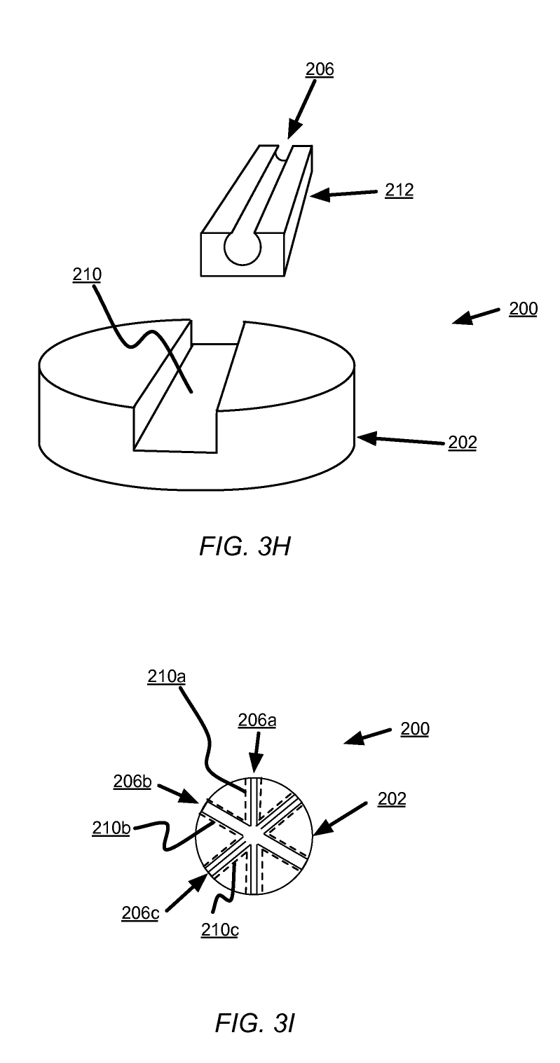

As illustrated in FIGS. 2A-2G, in some embodiments, a cable management module 200 may include a single cable retaining channel 206. For example, where cable management modules 200 are supplied with headphones 100, the user need not worry that the gauge of a cable 108 is too large or too small for the cable retaining channel 206. However, in embodiments in which cable management modules 200 are supplied separately or intended to be used with many different models of headphones or other devices, a cable management module may include multiple cable retaining channels, each in a different configuration and/or width. FIG. 3A is an isometric view of such an embodiment of a cable management module with multiple cable gauge capability. As shown, a plurality of cable retaining channels 206a-206c may be cut into an upper portion 204 of a cable management module 200. Each channel 206 may have a different width, different depth, different cross section, and may comprise a single channel or multiple sub-channels.

As shown in the top view of FIG. 3B, in some embodiments, channels 206a-206c may intersect or cross. Because typically only a single cable 108 may be installed into a cable management module 200 at one time, unused channels 206 may not interfere with the user's use of a first channel.

Referring briefly to FIG. 3C, illustrated are top views of additional embodiments of cable management modules 200. As shown, in some embodiments, cable retaining channels 206a-206c may intersect, while in other embodiments, cable retaining channels 206a-206c may not intersect, but may run parallel or not intersect on the face of cable management module 200. In many embodiments, cable management modules 200 need not be cylindrical, as illustrated in the bottom row of FIG. 3C. Instead, modules 200 may be different shapes, such as aesthetically pleasing shapes for fashion purposes, or shaped to protrude less from a cable 108 when installed. In a further embodiment, a cable management module 200 may be incorporated in an item of jewelry, such as a brooch, lapel pin, or necklace.

Furthermore, in some embodiments, multiple surfaces of a cable management module 200 may be utilized for cable retaining channels 206. FIG. 3D is an isometric view of yet another embodiment of a cable management module with multiple cable gauge capability. As shown, multiple cable retaining channels 206a-206c may be cut or molded into different sides of the cable management module 200. Accordingly, in many embodiments, a cable management module 200 may not comprise an upper portion 204 and lower portion 202, but may simple be a material encapsulating a magnet 208, with channels 206 cut into the module 200 in various locations. Referring briefly to FIG. 3E, isometric views of additional embodiments of cable management modules are illustrated, with different module shapes employed for aesthetic or functional purposes.

In embodiments in which different surfaces of a cable management module 200 include cable retaining channels, or where a face includes non-intersecting cable retaining channels, multiple cables 108 may be simultaneously installed into cable management module 200. For example, upper portions of cables for headphones are typically smaller than lower portions, as they only connect to a single transducer. A multiple-gauge cable management module may be employed to attach both to the upper portion and lower portion of the cable, preventing tangling during storage. In other embodiments, and discussed in more detail below in connection with FIG. 5, cable management modules may be used with other cables, including power cables, network cables, universal serial bus (USB) cables, etc. Different gauge channels may be used allowing a single cable management module to retain both a network cable and a USB cable, for example, for easier cable management with parallel runs of wires.

Although described in terms of cable management modules being added to a cable after manufacture, frequently by the user, in some embodiments, cable management modules may be installed during manufacture. Referring briefly to FIG. 3F, illustrated is an isometric view of still yet another embodiment of a cable management module 200. A cable retaining channel 206 may comprise a hole within a cable management module 200, and magnet 208 may comprise a torus shape around channel 206. As shown in FIG. 3G, in some embodiments, the cable management modules of FIG. 3F may be installed on a cable, reducing the amount that each module protrudes from the cable, while still retaining all of the functionality of the cable management system. In some embodiments, cable management module 200 may be molded on the wire or may be manufactured with the wire such that insulation of the wire also encompasses cable management module 200, providing a smooth exterior. Accordingly, in many embodiments, cable management modules 200a-200c may protrude significantly less from the surface of cable 108 than shown in FIG. 3G.

In some embodiments, a cable retaining channel 206 may be formed in a removable insert. For example, referring to FIG. 3H, a cable management module 200 may include a channel 210 for an insert 212. As shown, the insert 212 may include a cable retaining channel 206. As discussed above, the module may also include multiple channels 206 for retaining cables of different diameters, types, or profiles. Such multiple channels 206a-206c may be formed from multiple inserts 212 in corresponding channels 210a-210c, as shown in dashed line in FIG. 3I. Because compressibility of the channel walls may be provided by a compressible material of insert(s) 212, a cable retaining module 200 may include just a lower portion 202, which may be formed of a stiff material, such as plastic or metal. Removable inserts allow for use of inserts with different diameter channels or different channel profiles, which may reduce manufacturing costs by allowing a single lower portion 202 of a module 200, which may include an expensive magnet, to be used with any of several cheap molded inserts 212. The insert(s) 212 may be held in channel(s) 210 via an adhesive which may be placed within the channel or on the insert, or the insert(s) 212 may be compressed to fit under pressure within corresponding channel(s) 210. Adhesives may be permanent, or reusable, thus allowing the insert to be removed and replaced by a user.

In still other embodiments, a cable management module 200 may comprise two halves that are interlocked together during installation, similar to ferrite beads or chokes that may be installed on wires for high frequency noise suppression. In one such embodiment, a half-toroidal magnet 208 or a magnet in another shape may be placed in each half of cable management module 200, while in another embodiment, half of cable management module 200 may include a magnet 208 while the second half does not.

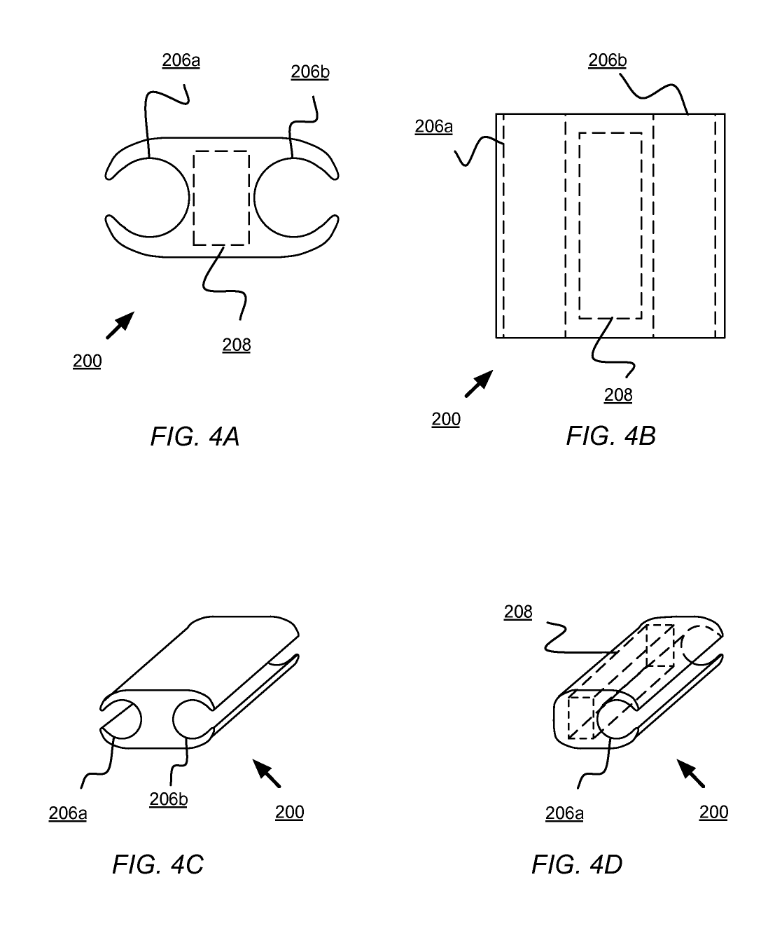

By attaching to a cable longitudinally, some embodiments of cable management module 200 may have a significantly reduced profile. Referring now to FIGS. 4A-4C, illustrated are front, top, and isometric views, respectively, of yet another embodiment of a cable management module. As shown, a cable management module 200 may include one or more cable channels 206a-206b running longitudinally along a side of cable management module 200. In many embodiments, each channel may have a cross section comprising most of a circle or cylinder, as shown. The cable management module 200 may be molded of a flexible or compressible substance, such as rubber, such that a user may press a cable into a channel 206 to affix cable management module 200 to the wire. Cable management module may include a magnet 208, which may be positioned between two channels 206 or adjacent to a channel 206. In many embodiments, magnet 208 may be encapsulated in the flexible or compressible substance, or otherwise encapsulated. As shown in FIGS. 4A-4C, cable management module 200 need not be much larger than the cable to which it is to be attached.

In a further embodiment illustrated in the isometric view of FIG. 4D, cable management module 200 may be even narrower, by including only a single channel. In such embodiments, cable management module 200 need only be large enough to encapsulate magnet 208 and form a substantial portion of channel 206 able to grasp and maintain a grip on a cable.

Although many of the embodiments discussed above utilize either a compressible or flexible substance around a cable retaining channel, or rely on the compressibility of an insulation material on a cable, in many embodiments, cable management modules 200 may include a closeable channel to securely grip a cable. For example, referring now to FIG. 5A-5C, illustrated are top, bottom, and front views, respectively, of yet still another embodiment of a cable management module 200. FIGS. 5A and 5B include section line A, and FIGS. 5D and 5E illustrate section views of embodiments of the cable management module of FIGS. 5A-5C in an unpressed and pressed state. Cable management module 200 may comprise a button 502 within an enclosure 504. A wide base 503 may be fixed to a terminal end of button 502, forming a stop, preventing button 502 from being removed from the enclosure 504. In some embodiments, button 502 may be held in an unpressed position via one or more springs 508a-508b. Button 502 may be attached to a hook 506, which may extend externally from enclosure 504 via holes 510a-510b. Hook 506 may enclose a space to retain a cable 206.

In use, a user may press button 502, moving hook 506 to a lower position as illustrated in FIG. 5E. The user may place a cable into the open space formed by hook 506, and may release the button 502. Hook 506 may then return to a default or closed position, as illustrated in FIG. 5D, securely holding the cable. Button 502 may further encapsulate a magnet 208.

Although illustrated in a square or cube shape, in many embodiments, enclosure 504 and/or button 502 may be round or cylindrical. In other embodiments, enclosure 504 and/or button 502 may be any other shape, including hexagonal, octagonal, semi-circular, or irregular. In some embodiments, a terminal end of hook 506 may meet with a corresponding hole in enclosure 504 as illustrated. In other embodiments, terminal end of hook 506 may meet with a notch, divot, or partial hole in enclosure 504 that does not penetrate fully through enclosure 504. In still other embodiments, terminal end of hook 506 may simply touch a flat surface of enclosure 504. Enclosure 504, button 502, base 503, and hook 506 may each be of metal, plastic, rubber, wood, ceramic, glass, or any other type and form of material or combination of materials. In some embodiments, one or more of enclosure 504, button 502, base 503 and hook 506 may be of different or dissimilar materials. For example, in one embodiment, enclosure 504 may be plastic, while hook 506 may be metal. Although shown in a U-shape, hook 506 may be any other shape, including square, rectangular, rounded, L-shaped, or any other shape. Hook 506 may have a round cross section, as a bent wire, or may have a square or rectangular cross section to position a greater surface area against a retained cable.

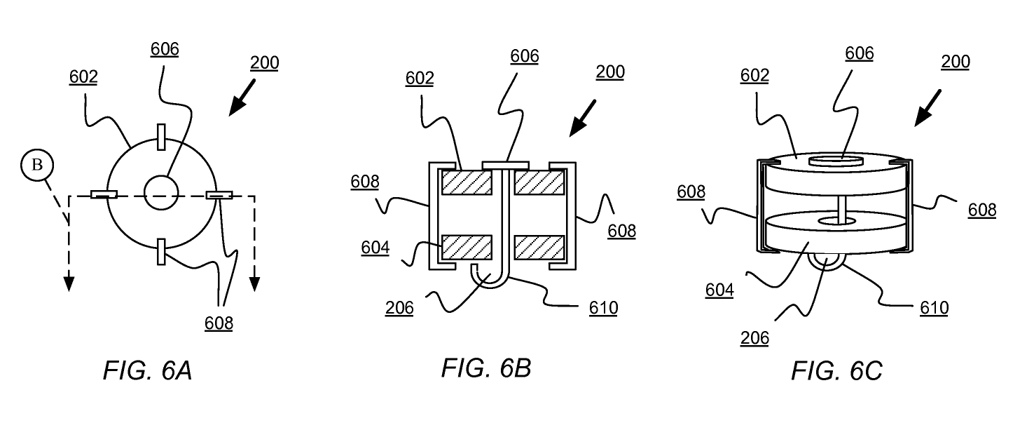

While the embodiments illustrated in FIGS. 5A-5E encapsulate a magnet and use springs to return a button 502 to an upper position, in other embodiments, the magnet itself may be used to provide a return force. Referring now to FIGS. 6A-6C, illustrated are top, section, and isometric views of yet another embodiment of a cable management module 200. FIG. 6A includes section line B, a view of which is shown in FIG. 6B. Cable management module 200 may comprise an upper magnet 602 and a lower magnet 604. Upper magnet 602 and lower magnet 604 may be positioned with the same poles facing each other, such that they are magnetically forced apart.

Magnets 602 and 604 may be constrained in their motion by one or more clips 608. Clips 608 may comprise a leg attached to an upper foot preventing upwards travel of upper magnet 602 and a lower foot preventing downwards travel of lower magnet 604. In some embodiments, clips 608 may be fixed to one of upper magnet 602 and lower magnet 604. In other embodiments, clips 608 may be fixed to a band or ring (not illustrated) holding clips 608 in position around upper magnet 602 and lower magnet 604. Any number of clips 608 may be used, including two, three, four, or any other number. In other embodiments, magnets 602 and 604 may be enclosed by a ring connected to an upper foot or upper retaining ring and lower foot or lower retaining ring. Thus, in many embodiments, magnets 602 and 604 may be laterally surrounded.

In some embodiments, a hook 610 may pass through a hole in lower magnet 604, enclosing a cable retaining channel 206. In one embodiment, hook 610 may be attached to upper magnet 602. In other embodiments, hook 610 may pass through a hole in upper magnet 602 and be fixed to a cap 606, as illustrated. Although shown contacting lower magnet 604, in some embodiments, hook 610 may contact a clip 608, lower retaining ring, or enclosure around magnets 602, 604.

Cap 606 may comprise a flat or rounded surface, and may be round, square, or any other shape. Although illustrated as circular, in many embodiments, cap 606, and magnets 602 and 604 may be square, rectangular, octagonal, or any other shape. In use, a user may press on cap 606 and/or upper magnet 602, lowering hook 610 from position against lower magnet 604, allowing the user to place a cable in channel 206. When the user releases the cap 606 and/or upper magnet 602, the upper magnet 602 and hook 610 may be returned to an upper position, with hook 610 securely gripping the cable.

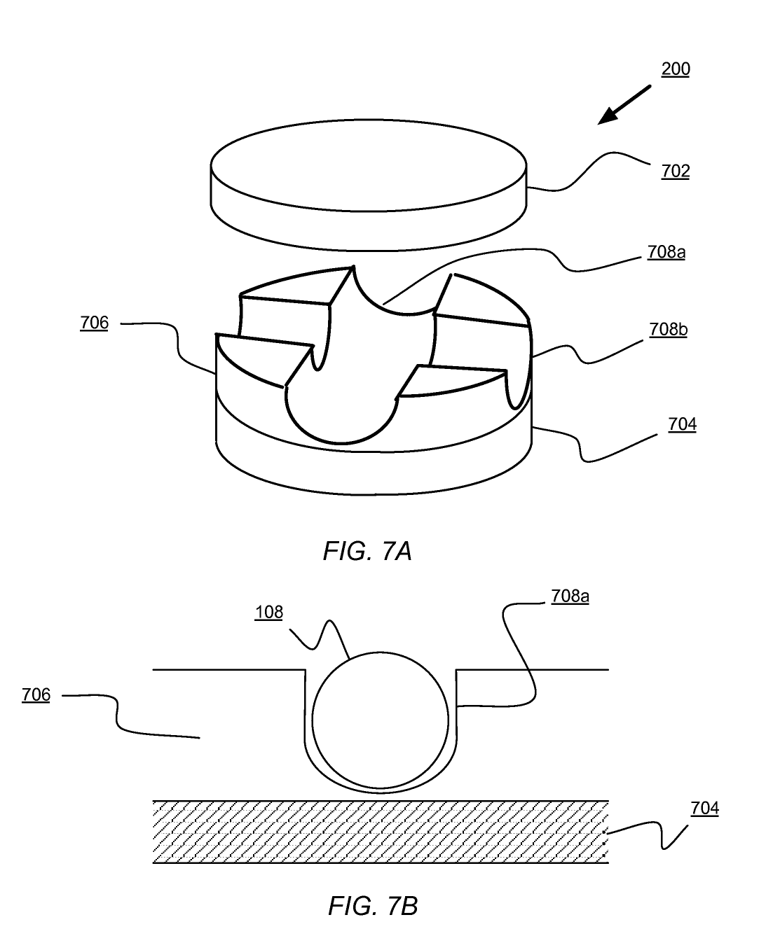

FIG. 7A is an isometric view of still yet another embodiment of a cable management module 200. An upper magnet 702 and lower magnet 704 may be positioned on either side of a cable retaining medium 706 with one or more cable retaining channels 708a-708b. Cable retaining medium 706 may be metal, plastic, rubber, ceramic, glass, or any other material, and may be fixed to lower magnet 704. In use, a user may place a cable in a cable retaining channel 708a-708b and place upper magnet 702 on top of the cable retaining medium 706. Upper magnet 702 may be held in place through attraction to cable retaining medium 706, in embodiments in which medium 706 is ferrous, and/or may be held in place through attraction to lower magnet 704. In such embodiments, because two magnets 702, 704, are utilized, each magnet may be individually smaller than in other embodiments of a cable management module 200. Accordingly, these embodiments may be significantly smaller overall.

Additionally, because upper magnet 702 may act as a cap, retaining a cable within a cable retaining channel, cable retaining medium 706 may have a height roughly equivalent to the diameter of a cable to be retained. Although shown as a continuous piece, in some embodiments, cable retaining medium 706 may comprise a plurality of pieces, with the bottom of a cable retaining channel 708 being formed by the upper surface of lower magnet 704. This may allow further reduction in height of cable retaining medium 706.

Referring briefly to FIG. 7B, illustrated is a section view of an embodiment of a channel of a cable management module. As shown, a cable retaining medium 706 may have a height of slightly less than a diameter of a cable 108 to be retained. When upper magnet 702 is attached to the cable retaining medium 706, cable 108 may be compressed slightly, providing friction and preventing the cable management module 200 from sliding along cable 108.

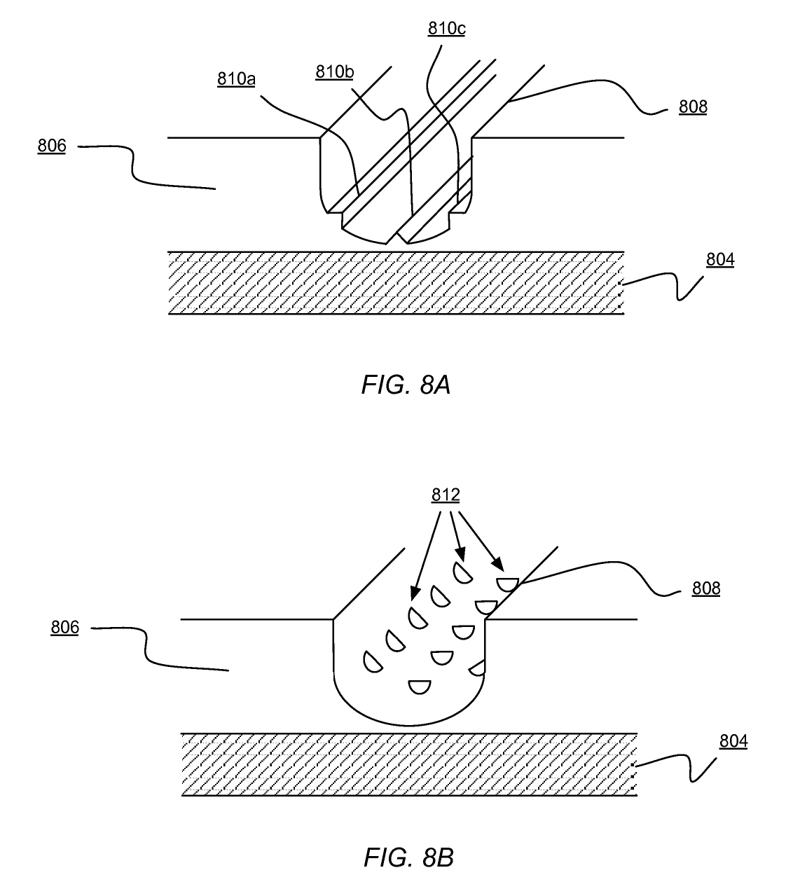

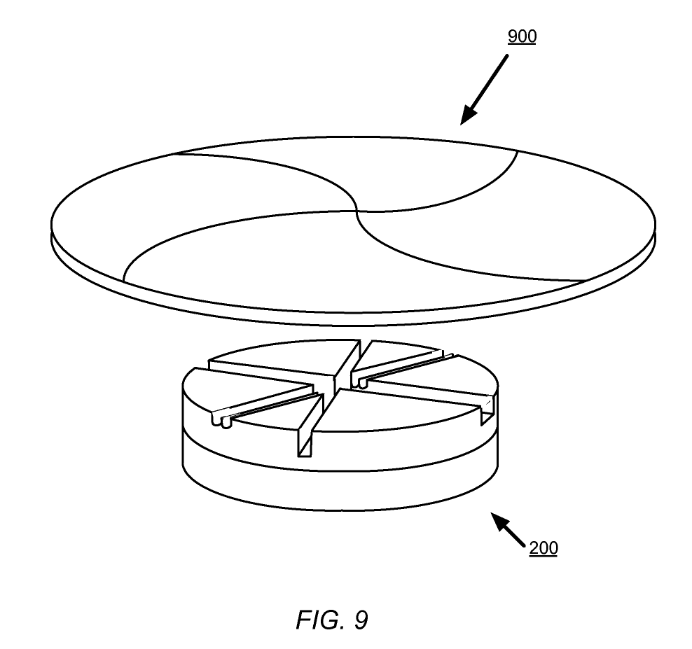

In some embodiments, a cable retaining channel may incorporate one or more ridges or teeth to grip a cable 108 to prevent a cable management module from sliding along a retained cable. FIGS. 8A and 8B are isometric views of embodiments of channels of a cable management module. Referring first to FIG. 8A, a cable retaining channel 808 may be notched or cut into a cable retaining medium 806 attached to a magnet 804. Cable retaining medium 806 may be metal, rubber, plastic, wood, ceramic, glass, or any other material. Cable retaining channel 808 may include one or more ridges 810a-810c, referred to generally as ridges 810. In some embodiments, each ridge 810 may be formed of the same material as cable retaining medium 806, such as rubber or molded plastic. In other embodiments, ridges 810 may be formed of a second material and glued within a cable retaining channel. In some embodiments, ridges 810 may be compressible. In other embodiments, ridges 810 may be non-compressible but compress insulation of a cable 108 inserted in cable retaining channel 808. Accordingly, ridges 810 may provide additional compression and friction on a cable, preventing the cable management module from sliding along the cable.

In another embodiment illustrated in FIG. 8B, a cable retaining channel 808 may comprise a plurality of scales, bumps, or teeth 812. In some embodiments, teeth 812 may be molded into cable retaining medium 806. By providing a plurality of teeth and corresponding points of compression on a cable 108 inserted into cable retaining channel 808, teeth 812 may prevent any longitudinal motion of cable 108 through channel 808.

While useful for cable management purposes, cable management modules 200 may also be useful as fashion accessories or for style enhancement. Because each module 200 includes a magnet, accessories made from ferromagnetic or magnetic materials may be attached on top of a module for display. Referring now to FIG. 9, illustrated is an isometric view of an embodiment of a fashion accessory 900 for a cable management module 200. In some embodiments, a fashion accessory 900 may comprise a disc, plate, cube, or other shape of a ferromagnetic material, such as iron or nickel. In other embodiments, a fashion accessory 900 may comprise a first non-magnetic material, such as silver or gold, precious stones, plastic, or any other type of material, and a second, magnetic material such as a ferromagnetic material, or a magnetic material such as a neodymium magnet. For example, a fashion accessory 900 may comprise an emerald and silver brooch, with a neodymium magnet backing that may magnetically attach to a cable management module. In other embodiments, a fashion accessory 900 may comprise a plastic disc or surface to which a sticker may be attached, such as a favorite pop star's image, a pleasing design, a humorous slogan, or any other image or text. Because the accessory 900 is only attached magnetically to the module 200, the accessory 900 may be easily replaced by the user to coordinate with outfits.

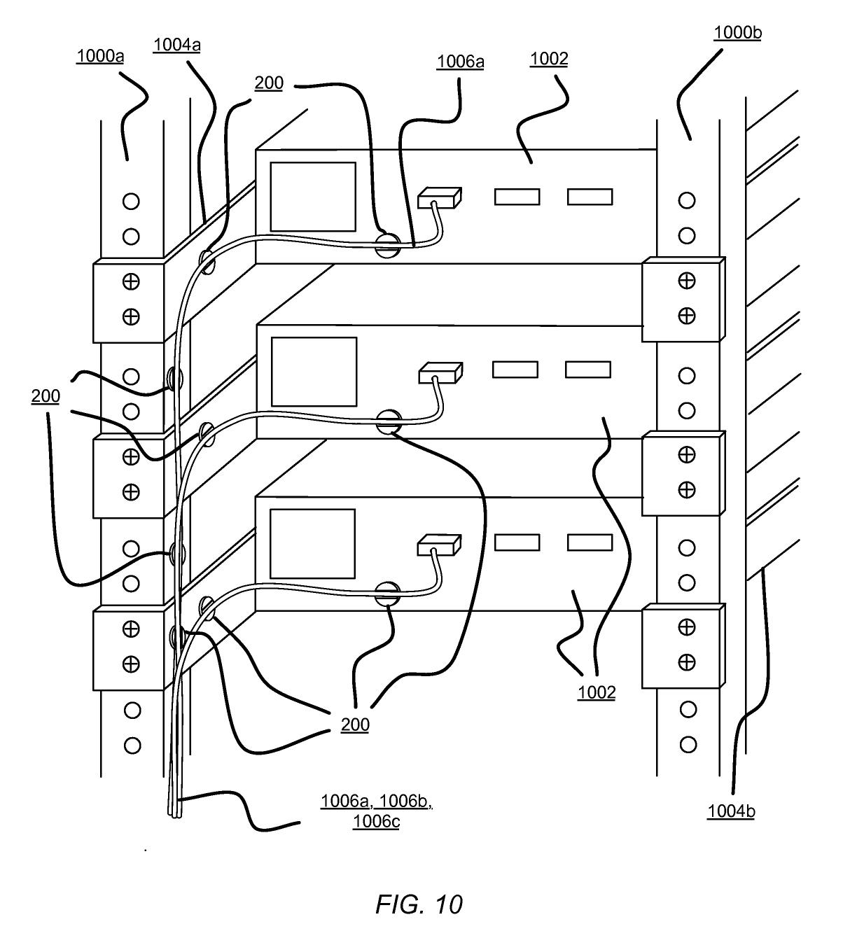

The cable management systems discussed herein may be utilized in many other industries and areas. For example, although discussed above in terms of headphone cable management for personal electronics, the same cable management modules may be utilized with power cables, network cables, USB cables, monitor cables, video cables, audio cables, or any other type and form of cable. For example, cable management modules may be used to secure cables in a server environment without requiring cable ties that may crimp or damage conductors, or require tedious cutting and re-harnessing every time a cable is moved. Referring now to FIG. 10, illustrated is an isometric view of an embodiment of use of a cable management system. A rack comprising vertical rack bars 1000a-1000b may attach to server rack mounts 1004a-1004b holding one or more servers or rack-mount computing devices 1002. Each computing device 1002 may be connected by one or more cables 1006a-1006c, such as USB cables, power cables, video cables, network cables, or any other type and form of cable. A plurality of cable management modules 200 with one or more cable retaining channels may be installed on each cable 1006a-1006c.

Because server rack bars 1000a-1000b and rack mounts 1004a-1004b are frequently made from ferrous materials, cable management modules 200 may be magnetically attached directly to these components to securely hold cables 1006a-1006c. When components are moved, modules 200 may be easily repositioned, both on the surface and along each cable.

In similar embodiments, cable management modules may be used with desktop or laptop computers for routing cables along a surface, such as a metal leg of a table or side of a desktop computer case, metal shelving, floor standing lamps, or any other components. Additionally, because modules 200 attach to the surfaces magnetically, if a user trips over a cable, the module 200 will pull away from the surface, reducing chances for injury as well as damage to the cable or device.

While various embodiments of the methods and systems have been described, these embodiments are exemplary and in no way limit the scope of the described methods or systems. Those having skill in the relevant art can effect changes to form and details of the described methods and systems without departing from the broadest scope of the described methods and systems. Thus, the scope of the methods and systems described herein should not be limited by any of the exemplary embodiments and should be defined in accordance with the accompanying claims and their equivalents.

What is claimed:

1. A cable management system, comprising:
a plurality of cable management modules, each comprising an enclosure comprising a first portion and an attached second portion, the first portion encapsulating a magnetic material, and the second portion comprising a compressible material forming a cable retaining channel, the cable retaining channel having an inside diameter of less than or equal to the diameter of a cable to be retained.

2. The cable management system of claim 1, wherein the cable retaining channel of each cable management module extends across a face of the enclosure.

3. The cable management system of claim 1, wherein the cable retaining channel of each cable management module is open along the length of the channel to allow insertion of the cable.

4. The cable management system of claim 1, wherein the cable retaining channel of each cable management module is encapsulated by the first portion of said cable management module.

5. The cable management system of claim 1, wherein a first cable management module is configured to be magnetically attached to a second cable management module, and wherein a third cable management module is configured to be magnetically attached to a magnetic transducer connected to a cable to be retained.

6. The cable management system of claim 1, wherein the second portion of each cable management module further comprises a compressible material forming a plurality of cable retaining channels extending across a face of the enclosure, each cable retaining channel having a different diameter or cross-sectional profile.

7. The cable management system of claim 1, wherein the second portion of each cable management module further comprises a compressible material forming a second cable retaining channel extending across a second face of the enclosure, each cable retaining channel having a different diameter or cross-sectional profile.

8. The cable management system of claim 1, wherein the first portion and the second portion of each cable management module are attached along a face of the second portion of said cable management module.

9. The cable management system of claim 1, wherein one of the first portion and the second portion of each cable management module encapsulates the other of said first portion and second portion of said cable management module.

10. The cable management system of claim 1, wherein the first portion of each cable management module further comprises a channel corresponding to dimensions of the second portion of said cable management module, and wherein the second portion is attached within the channel of said first portion.

11. The cable management system of claim 10, wherein the first portion of each cable management module further comprises a plurality of channels corresponding to dimensions of a corresponding plurality of second portions of said cable management module, each second portion attached within a corresponding channel of said first portion.

12. The cable management system of claim 1, wherein a surface of a cable retaining channel of each cable management module comprises at least one ridge or scale.

13. The cable management system of claim 1, wherein each cable management module further comprises a third portion magnetically attached to one of the second portion or first portion of said cable management module.

14. The cable management system of claim 13, wherein the third portion comprises a fashion accessory.

15. The cable management system of claim 1, further comprising a cable connected to one or more audio transducers, a portion of the cable retained by each cable retaining channel of the plurality of cable management modules.

16. The cable management system of claim 1, wherein the cable management module further comprises a third portion forming an opposing surface of the cable retaining channel from a surface of the second portion.

17. The cable management system of claim 16, wherein the third portion encapsulates a magnetic material.

18. The cable management system of claim 16, wherein the second portion of each cable management module comprises a hook to form the cable retaining channel.

19. The cable management system of claim 18, wherein the third portion is attached to the first portion or second portion via at least one spring.

20. The cable management system of claim 18, wherein the third portion is magnetically repelled from the first portion, and wherein each cable management module further comprises at least one clip to constrain movement of the first and third portions.
